(19) United States
(12) Patent Application Publication
(10) Pub. No.: US 2011/0133769 A1
(43) Pub. Date: Jun. 9, 2011

(54) INSPECTION APPARATUS AND METHOD FOR LED PACKAGE INTERFACE

(75) Inventors: Chiu Ling CHEN, ZhudongTownship (TW); Fei Chang Hwang, Miaoli City (TW); Chien Ping Wang, Kouhu Township (TW); Sheng Pan Huang, Xihua Township (TW)

(73) Assignee: INDUSTRIAL TECHNOLOGY RESEARCH INSTITUTE, Hsinchu (TW)

(21) Appl. No.: 12/823,859

(22) Filed: Jun. 25, 2010

(30) Foreign Application Priority Data
Dec. 9, 2009 (TW) 098142003

(51) Int. Cl. G01R 31/26; G01R 31/02

(52) U.S. Cl. 324/762.07

(57) ABSTRACT

An LED package interface inspection apparatus for an LED device comprises a current source, a voltage measuring unit, and a testing control unit. The testing control unit provides at least one control signal to command the current source to output at least one current for the LED device. The testing control unit also provides at least two signals to command the voltage measuring unit to measure a first forward voltage of the LED device at a first time and a second forward voltage of the LED device at a second time. The testing control unit calculates a voltage difference between the first forward voltage and the second forward voltage, and determines that the LED device is defective if the voltage difference is larger than a predetermined threshold value.

### CROSS-REFERENCE TO RELATED APPLICATIONS

This application is an application under 35 U.S.C. 111(a) and claims priority under 35 U.S.C. 119 from Taiwanese Patent Application No. 098142003 filed Dec. 9, 2009, the disclosure of which is incorporated herein by reference.

### STATEMENT REGARDING FEDERALLY SPONSORED RESEARCH OR DEVELOPMENT

Not applicable.

### NAMES OF THE PARTIES TO A JOINT RESEARCH AGREEMENT

Not applicable.

### INCORPORATION-BY-REFERENCE OF MATERIALS SUBMITTED ON A COMPACT DISC

Not applicable.

### BACKGROUND OF THE INVENTION

1. Field of the Invention

The present invention relates to an inspection apparatus and a method for a light emitting diode (LED) package interface.

2. Description of Related Art Including Information Disclosed Under 37 CFR 1.97 and 37 CFR 1.98

A light emitting diode (LED) package process comprises steps of die bonding, wire bonding, encapsulation, and inspection, wherein the die bonding step uses a die bonding material, such as silver paste, eutectic alloy, or thermal conductive adhesive, for adhering LED dies to a package carrier or a substrate. If the thickness of the die bonding material is non-uniform, if voids occur in the die bonding material, or if the material ages during the die bonding step, such conditions will result in variances in characteristics of the die bonding material. With current process technology, the inspection step for sorting unqualified die bonding devices cannot be performed rapidly enough by the general apparatuses of rapid optical and electrical properties inspection. The unqualified die bonding material results in greater thermal resistance and poor heat conduction so that the LED devices may have problems with overheating, early light degradation, or burnout during consumer use.

The current process to evaluate the thermal conduction of LED devices utilizes a thermal resistance measurement apparatus for measuring thermal resistance based on industry standards including JEDEC-51, MIL-STD-883, and CNS 15248. However, the thermal resistance measurement step is too complex and time-consuming to be adopted for real-time quality inspection of LED package devices.

### BRIEF SUMMARY OF THE INVENTION

The present invention provides a rapid inspection apparatus and a method for an LED package interface which reduces time spent measuring the thermal conduction of LED devices. Differences in measurable qualities of the package interface, such as die bonding quality, between LED devices can be determined within seconds. The inspection apparatus and method of the present invention can be combined with the general apparatuses of rapid optical and electrical properties inspection for sorting unqualified die bonding devices before the LED devices are shipped from the factory.

According to one exemplary embodiment, the LED package interface inspection apparatus for an LED device includes a current source, a voltage measuring unit, and a testing control unit. The testing control unit provides at least one control signal to command the current source to output at least one current to the LED device, and provides at least two signals to command the voltage measuring unit to measure a first forward voltage of the LED device at a first time and a second forward voltage of the LED device at a second time. The testing control unit calculates a voltage difference between the first forward voltage and the second forward voltage, and determines that the LED device is defective if the voltage difference is larger than a predetermined threshold value.

According to another exemplary embodiment, the LED package interface inspection method for an LED device includes providing at least one current to the LED device, measuring a first forward voltage of the LED device at a first time and measuring a second forward voltage of the LED device at a second time with the at least one current, calculating a voltage difference between the first forward voltage and the second forward voltage, and determining whether the LED device is defective based on whether the voltage difference is larger than a predetermined threshold value.

According to yet another exemplary embodiment, the LED package interface inspection method for a plurality of LED devices includes providing at least one testing current, measuring a first forward voltage of each LED device at a first time and measuring a second forward voltage of each LED device at a second time with the testing current, calculating a voltage difference between the first forward voltage and the second forward voltage of each LED device, and classifying the plurality of LED devices according to the voltage difference of each LED device.

Another exemplary embodiment includes a computer program product for inspecting a package interface of an LED device. The computer program product comprising a computer readable storage medium having computer-readable program instructions embodied in the medium, the computer-readable program instructions comprising first instructions for providing at least one current to the LED device, second instructions for measuring a first forward voltage of the LED device at a first time and measuring a second forward voltage of the LED device at a second time with the at least one current, third instructions for calculating a voltage difference between the first forward voltage and the second forward voltage, and fourth instructions for determining whether the LED device is defective based on whether the voltage difference is larger than a predetermined threshold value.

### BRIEF DESCRIPTION OF THE SEVERAL VIEWS OF THE DRAWINGS

The accompanying drawings, which are incorporated in and constitute a part of this specification, illustrate embodiments of the present invention and, together with the description, serve to explain the principles of the invention.

FIG. 1 shows a diagram of a package interface of an LED device assembled on a circuit board in accordance with an exemplary embodiment;

FIG. 2 shows a diagram of a relation between a voltage difference and time in accordance with an exemplary embodiment;

FIG. 3 shows a block diagram of an LED package interface inspection apparatus;

FIG. 4 shows a flow chart of one embodiment of the LED package interface inspection method of the present invention

FIG. 5 shows a diagram of a relation between the current and the forward voltage in accordance with a first embodiment of the present invention;

FIG. 6 shows a diagram of a relation between the current and the forward voltage in accordance with a second embodiment of the present invention;

FIG. 7 is a diagram showing experimental results in which the value of the voltage difference dv increases over time;

FIG. 8 shows a diagram of a relation between the current and the forward voltage in accordance with a third embodiment of the present invention;

FIG. 9 shows a diagram of a relation between the current and the forward voltage in accordance with a fourth embodiment of the present invention;

FIG. 10 shows a diagram of a relation between the current and the forward voltage in accordance with a fifth embodiment of the present invention;

FIG. 11 shows a diagram of a relation between the current and the forward voltage in accordance with a sixth embodiment of the present invention;

FIG. 12 shows a diagram of a relation between the current and the forward voltage in accordance with a seventh embodiment of the present invention;

FIG. 13 shows a diagram of a relation between the current and the forward voltage in accordance with an eighth embodiment of the present invention;

FIG. 14 shows a diagram of a relation between the current and the forward voltage in accordance with a ninth embodiment of the present invention;

FIG. 15 shows a diagram of a relation between the current and the forward voltage in accordance with an tenth embodiment of the present invention; and

FIG. 16 shows the flow chart of another embodiment of the LED package interface inspection method of the present invention.

### DETAILED DESCRIPTION OF THE INVENTION

Exemplary embodiments will now be described more fully with reference to the accompanying drawings. The present invention may, however, be embodied in many different forms and should not be construed as limited to the embodiments set forth herein. Rather, these embodiments are provided so that this present invention will be thorough and complete, and will fully convey the scope of the present invention to those skilled in the art.

The junction temperature of an LED device with unqualified die bonding interface is higher than that of an LED device with qualified die bonding interface when the same rated current flows through both LED devices. Based on the above characteristic, the present invention provides a method for inspecting LED package interfaces instantaneously so as to resolve complex and time-consuming issues associated with sorting the LED devices by measuring thermal resistance of LED devices in a conventional way.

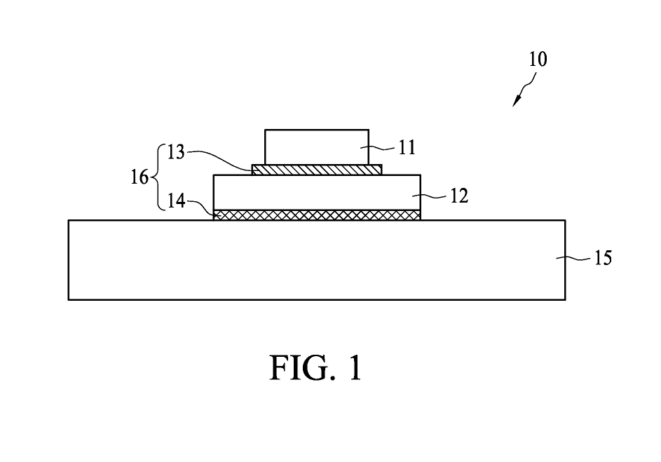

FIG. 1 shows a diagram of a package interface of an LED device 10 assembled on a circuit board in accordance with an exemplary embodiment, wherein an LED die 11 is die bonded on a package carrier 12, and a die-bonding interface 13 is formed between the die 11 and the package carrier 12. The die-bonding interface 13 can comprise silver paste, eutectic alloy, thermal conductive adhesive, etc. The LED device 10 includes the LED die 11, the die-bonding interface 13, and the package carrier 12. The package carrier 12 is assembled on a circuit board 15, and an assembly interface 14 is formed between the package carrier 12 and the circuit board 15. In particular, a package interface 16 related to heat dissipation of the LED die 11 includes the die-bonding interface 13 and the assembly interface 14.

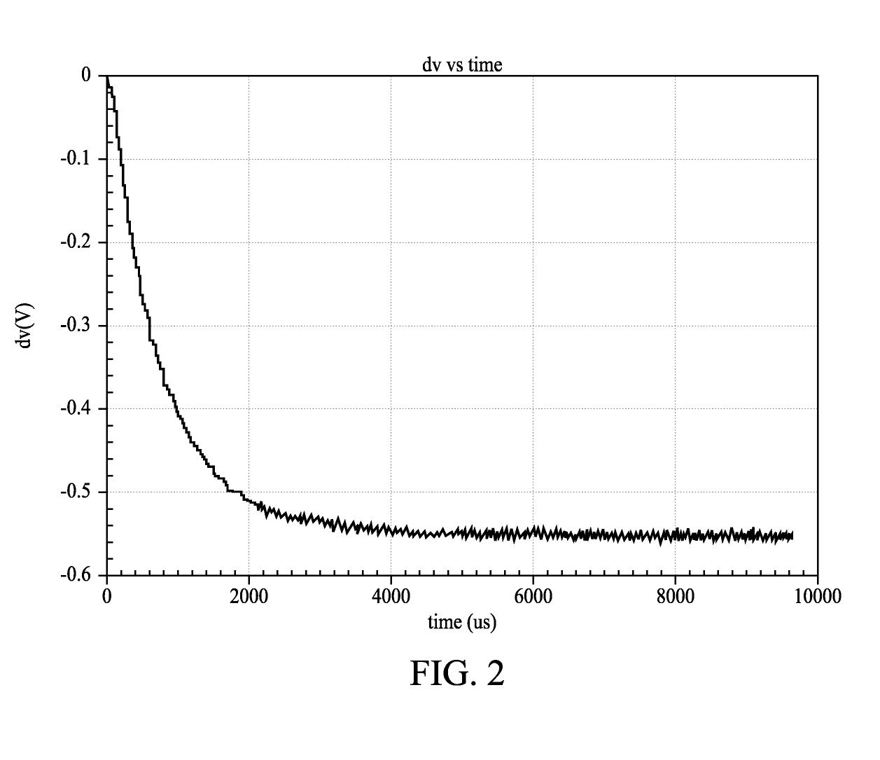

The measurement principle of the present invention is based on the phenomenon of an increase of the LED junction temperature resulting in a decrease in LED forward voltage. When a current flows through an LED device, a pn junction of the LED device luminesces and produces heat. Therefore, the junction temperature of the LED device increases, and the forward voltage of the LED device decreases. As the forward voltage of the LED device decreases, a voltage difference dv (a negative value), i.e., a second forward voltage V2 minus a first forward voltage V1, increases as shown in FIG. 2. On the condition that the same currents flow through the same LED dies, the increasing rate of reduction of the LED forward voltage has a relation with the heat conducting outward. When the heat generated by the LED device is hindered from conducting outward, the increasing rate of reduction of the LED forward voltage will increase. That is, the LED device with the lesser outward heat conduction ability exhibits a larger forward voltage difference, which is measured between the time at which a current is initially applied to the LED device and the time at which the heat of the LED device is conducted to the assembly interface.

During the package process of the LED device, an unqualified die-bonding interface can be sorted out by the above measurement of the forward voltage difference. Moreover, when the LED device is assembled to a circuit board or a heat dissipation metal plate, a high thermal resistance interface formed due to an unqualified assembly interface can be sorted out according to the above measurement of the forward voltage difference.

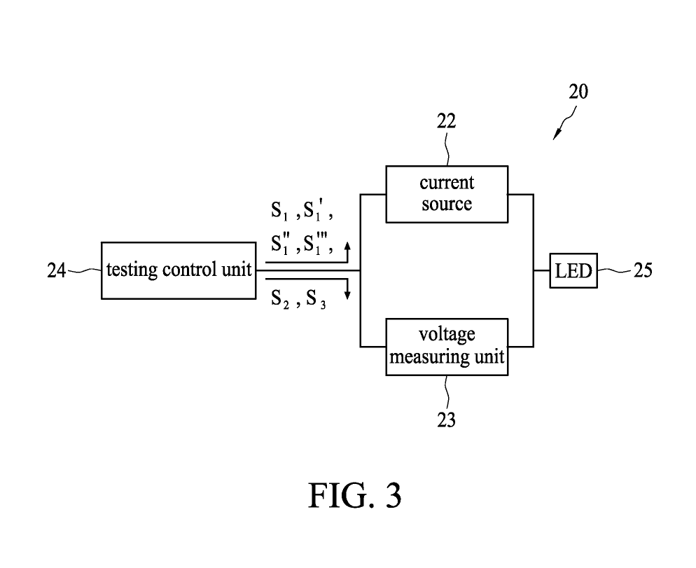

In order to explain the LED package interface inspection method of the present invention more clearly, an inspection apparatus that performs the method of the present invention is described as follows. FIG. 3 shows a block diagram of an LED package interface inspection apparatus 20 according to one embodiment of the present invention. Referring to FIG. 3, the LED package interface inspection apparatus 20 includes a current source 22, a voltage measuring unit 23, and a testing control unit 24. According to one embodiment, an LED device 25 is similar to the LED device 10 shown in FIG. 1.

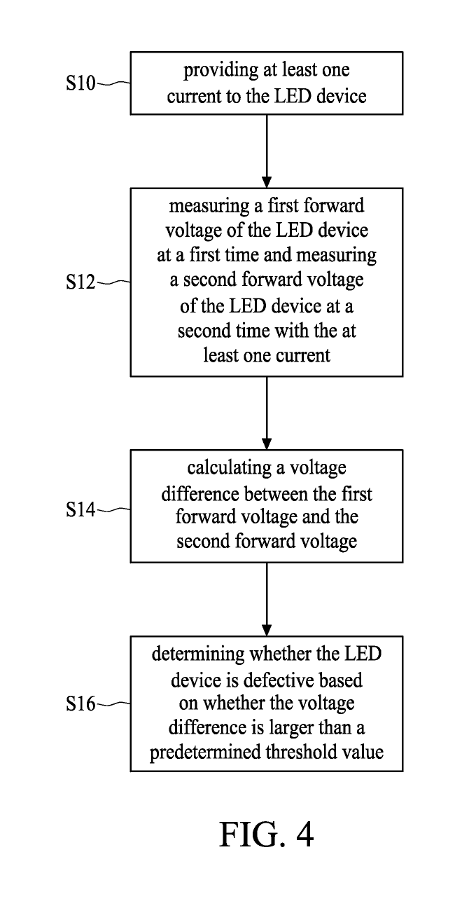

FIG. 4 shows a flow chart of one embodiment of the LED package interface inspection method of the present invention, which includes providing at least one current to the LED device in step S10, measuring a first forward voltage of the LED device at a first time and measuring a second forward voltage of the LED device at a second time with the at least one current in step S12, calculating a voltage difference between the first forward voltage and the second forward voltage in step S14, and determining whether the LED device is defective based on whether the voltage difference is larger than a predetermined threshold value in step S16.

Hereinafter, referring to FIGS. 3 and 4, the detailed inspection apparatus and method in accordance with embodiments of the present invention is introduced.

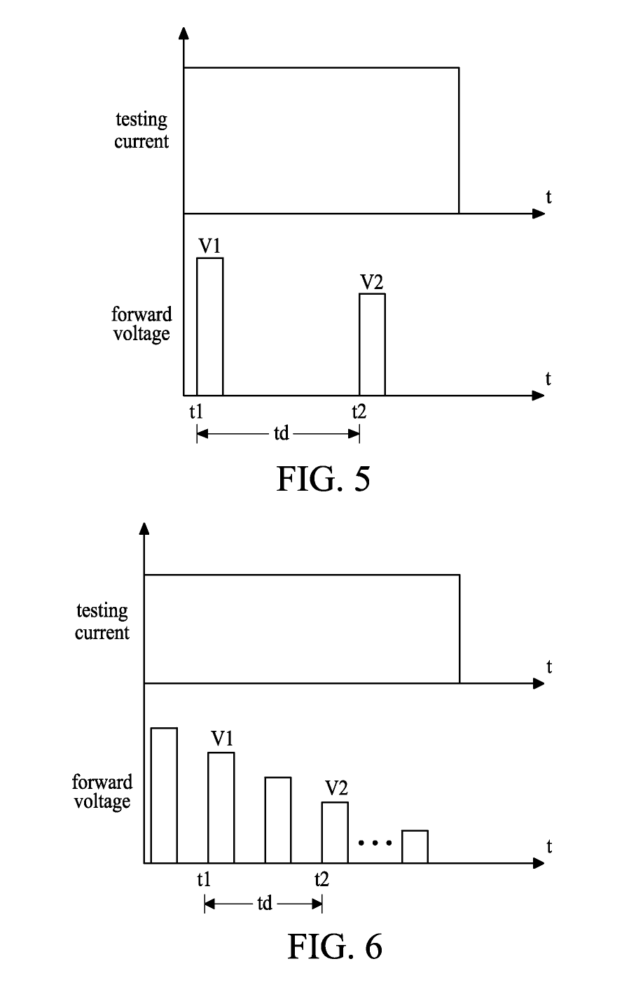

In a first embodiment of the present invention as shown in FIG. 5, the testing control unit 24 provides at least one control signal S1 to command the current source 22 to generate at least one current for the LED device 25, and provides at least two signals S2 and S3 to command the voltage measuring unit 23 to measure forward voltages of the LED device 25 so as to obtain a first forward voltage V1 at a first time and a second forward voltage V2 at a second time. In other words, the current source 22 provides at least one current to the LED device according to the control signal S1 from the testing control unit 24, and the voltage measuring unit 23 measures the two forward voltages of the LED device 25 according to the signals S2 and S3 from the testing control unit 24. However, the structure of the apparatus disclosed by the present invention should not be limited to the embodiments set forth herein, and can be varied according to the practical application.

The testing control unit 24 reads and records the two forward voltages V1 and V2 of the LED device 25 measured by the voltage measuring unit 23, calculates the voltage difference of the voltages V1 and V2, and then determines that the LED device 25 is defective if the voltage difference is larger than a predetermined threshold value.

In a second embodiment of the present invention, the testing control unit 24 provides at least one control signal S1 to command the current source 22 to generate at least one current for the LED device 25, and provides at least two signals S2 and S3 to command the voltage measuring unit 23 to continuously measure forward voltages of the LED device 25 so as to obtain a plurality of forward voltages including voltages V1 and V2 at different times as shown in FIG. 6. In other words, the current source 22 provides at least one current to the LED device according to the control signal S1 from the testing control unit 24, and the voltage measuring unit 23 measures the plurality of forward voltages of the LED device 25 according to the signals S2 and S3 from the testing control unit 24.

Moreover, the testing control unit 24 reads and records the plurality of forward voltages of the LED device 25 measured by the voltage measuring unit 23, and calculates the voltage difference between two forward voltages V1 and V2 of the LED device 25 measured at two predetermined times t1 and t2, wherein the plurality of forward voltages decreases continuously over time, and the value of the forward voltage V1 is larger than that of the forward voltage V2. Subsequently, the testing control unit 24 determines that the LED device 25 is defective if the voltage difference between the forward voltages V1 and V2 is larger than a predetermined threshold value.

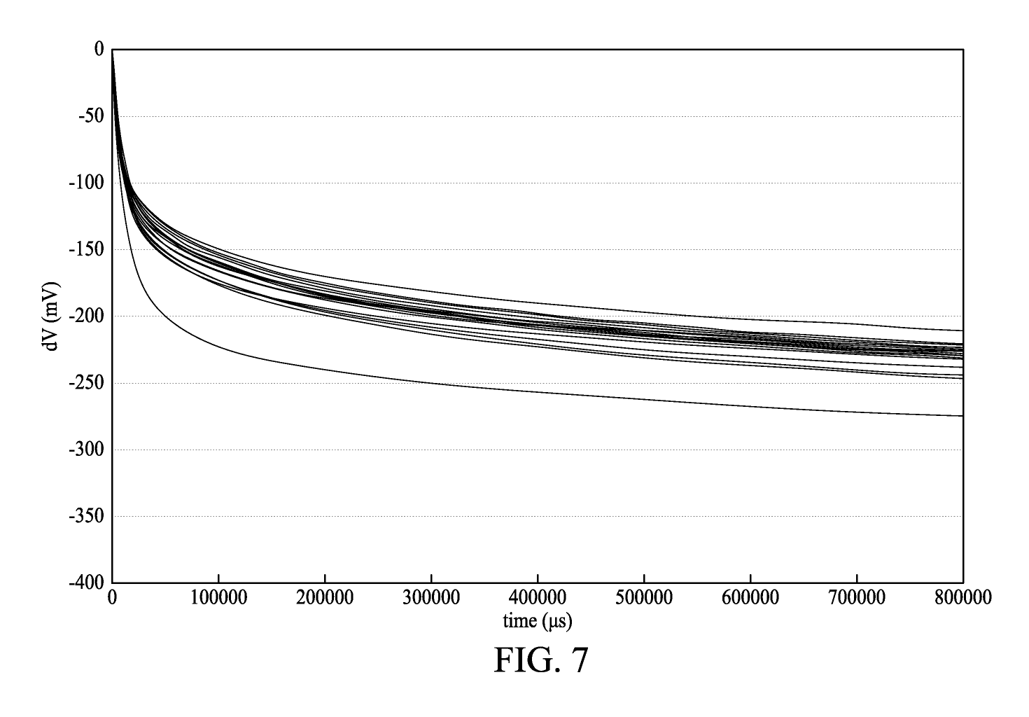

The predetermined threshold value is set according to the package structure of the LED device and the interval between two measuring times. Poorer heat conduction of the package structure of the LED device corresponds to larger voltage difference. Also, for the same LED device, a longer interval between two measuring times corresponds to a larger voltage difference. FIG. 7 is a diagram showing experimental results in which the value of the voltage difference dv increases over time. A plurality of forward voltages of twenty blue LEDs are measured at different times by providing a test current 350 mA. A first forward voltage V1 is measured when the test current is provided for 20 μsec, and the values of the voltage difference dv, i.e., all other forward voltages minus the first forward voltage V1, are obtained at different times as shown in FIG. 7. A second forward voltage V2 is measured when the test current is provided for 100000 μsec. Accordingly, if the voltage difference of any LED device is larger than a predetermined threshold value, i.e., 200 mV, the LED device is determined to be defective. Moreover, if a second forward voltage V2 is measured when the test current is provided for 500000 μsec, a threshold value of 250 mV is set.

In the first and second embodiments, the testing current provided by the current source 22 can be a pulse current or a direct current, and the value of the testing current can be set according to the structure of the LED device 25. A rated current value of the LED device 25 with 1 mm² LED die area, for example, about 250 mA to 350 mA, is generally adopted. Moreover, a rated current value of the LED device 25 with 0.1 mm² LED die area, for example, about 10 mA to 20 mA, is generally adopted. In addition, a time interval td of the voltage measurement can be set according to the value of the testing current and the types and the structures of the LED device 25, and the general time interval td is between 100 μsec and 1 sec. However, the present invention should not be limited to the first and second embodiments.

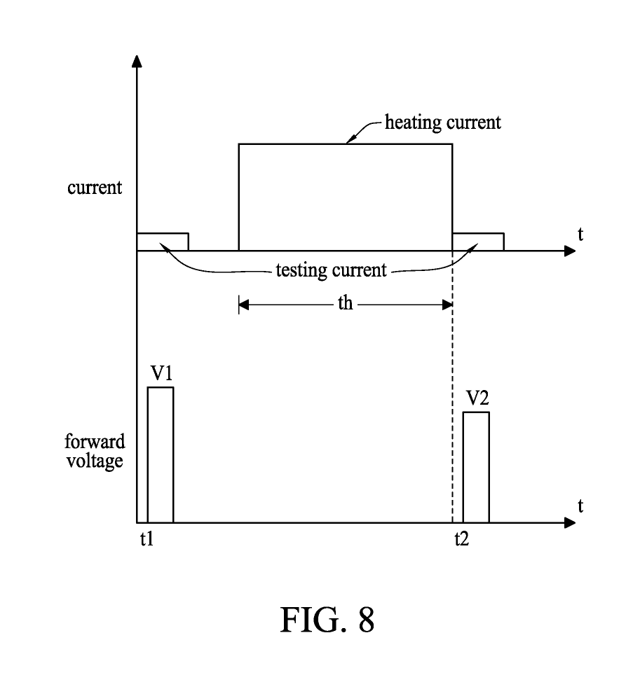

In a third embodiment of the present invention as shown in FIG. 8, the testing control unit 24 provides a first control signal S1 to command the current source 22 to generate a testing current for the LED device 25, and provides a signal S2 to command the voltage measuring unit 23 to measure a forward voltage V1 of the LED device 25. Subsequently, the testing control unit 24 provides a second control signal S1′ to command the current source 22 to generate a heating current for the LED device 25. After a heating interval th, the testing control unit 24 provides a third control signal S1″ to command the current source 22 to stop the heating current and to generate the testing current in turn, and provides another signal S3 to command the voltage measuring unit 23 to measure a forward voltage V2 of the LED device 25 at a second time t2.

Subsequently, the testing control unit 24 reads and records the forward voltages V1 and V2 of the LED device 25 measured by the voltage measuring unit 23, and calculates the voltage difference between them. Subsequently, the testing control unit 24 determines that the LED device 25 is defective if the voltage difference is larger than a predetermined threshold value.

In this embodiment, the testing current provided by the current source 22 can be a pulse current with a pulse width about 20 μsec to 100 μsec, and the value of the testing current can be set according to the structure of the LED device 25. A small current value of the LED device 25, for example, between 0.1 mA and 5 mA, is generally adopted. The heating current provided by the current source 22 can be a pulse current or a direct current, and the value of the heating current can be set according to the structure of the LED device 25. A rated current value of the LED device 25 is generally adopted. In addition, the heating interval th can be set according to the value of the testing current and the types and the structures of the LED device 25, and the heating interval th is generally between 100 μsec and 1 sec. Compared to the first embodiment, the testing current in the third embodiment is smaller, and thus errors caused by extra heat, due to large current heat generation, can be avoided.

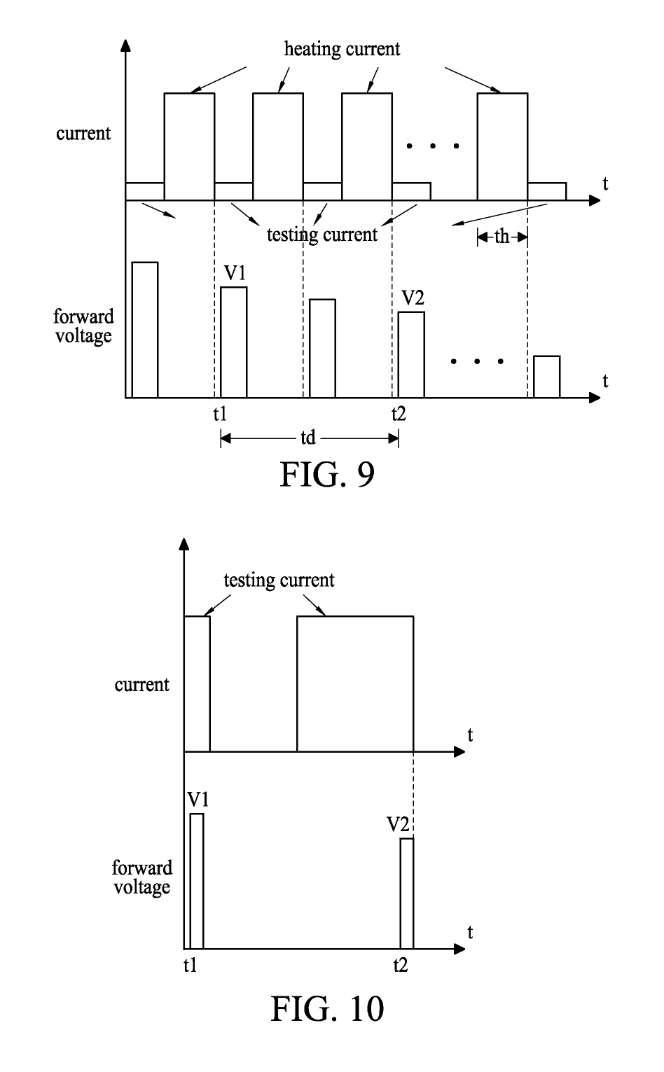

Similarly, for obtaining a plurality of forward voltages including voltages V1 and V2 at different times in accordance with a fourth embodiment as shown in FIG. 9, the current source 22 alternately provides the testing current and the heating current to the LED device 25, wherein the current source 22 provides the heating current to the LED device 25 during a heating interval th before providing the testing current. After the heating interval th, the testing control unit 24 provides at least two signals S2 and S3 to command the voltage measuring unit 23 to measure the plurality of forward voltages of the LED device 25.

The testing control unit 24 reads and records the plurality of forward voltages of the LED device 25 measured by the voltage measuring unit 23, and calculates the voltage difference between two of the forward voltages V1 and V2 of the LED device 25 measured at two predetermined times t1 and t2, wherein the plurality of forward voltages decreases continuously over time, and the value of the forward voltage V1 is larger than that of the forward voltage V2. Subsequently, the testing control unit 24 determines that the LED device 25 is defective if the voltage difference between the forward voltages V1 and V2 is larger than a predetermined threshold value.

In a fifth embodiment of the present invention as shown in FIG. 10, the testing control unit 24 provides a first control signal S1 to command the current source 22 to generate a first testing current for the LED device 25, and provides a signal S2 to command the voltage measuring unit 23 to measure a forward voltage V1 of the LED device 25. Subsequently, the testing control unit 24 provides a second control signal S1′ to command the current source 22 to generate a second testing current for the LED device 25, and provides another signal S3 to command the voltage measuring unit 23 to measure a forward voltage V2 of the LED device 25. In this embodiment, the first and the second testing current are pulse currents, and the values of the first and second testing currents are equal to the rated current value of the LED device. As shown in FIG. 10, the pulse width of the first testing current is between 20 μsec to 100 μsec, and the pulse width of the second testing current is greater than that of the first testing current. The pulse width of the second testing current is between 100 μsec and 1 sec, causing the junction temperature of the LED device to increase due to the second testing current after the first time.

The testing control unit 24 reads and records the forward voltages V1 and V2 of the LED device 25 measured by the voltage measuring unit 23, and calculates the voltage difference between them. Subsequently, the testing control unit 24 determines that the LED device 25 is defective if the voltage difference is larger than a predetermined threshold value.

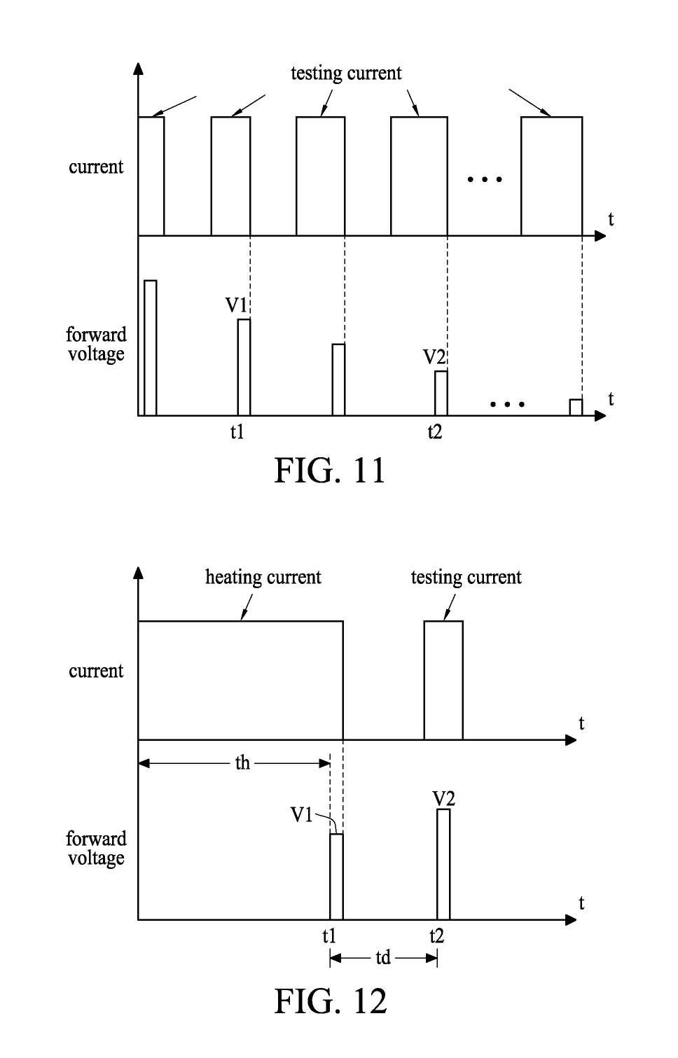

Similarly, for obtaining a plurality of forward voltages at different times in accordance with a sixth embodiment as shown in FIG. 11, the testing control unit 24 provides a plurality of control signals to command the current source 22 to generate a pulse current produced in sequence with gradually increased pulse widths for the LED device 25, and provides a plurality of signals to command the voltage measuring unit 23 to continuously measure forward voltages of the LED device 25. The junction temperature of the LED device 25 increases due to the pulse current with gradually increased pulse widths over time.

The testing control unit 24 reads and records the plurality of forward voltages of the LED device 25 measured by the voltage measuring unit 23, and calculates the voltage difference between two forward voltages V1 and V2 of the LED device 25 measured at two predetermined times t1 and t2, wherein the plurality of forward voltages decreases continuously over time, and the value of the forward voltage V1 is larger than that of the forward voltage V2. Subsequently, the testing control unit 24 determines that the LED device 25 is defective if the voltage difference between the forward voltages V1 and V2 is larger than a predetermined threshold value.

In addition, a decrease of the LED junction temperature will result in an increase in LED forward voltage. After a heating current flows through an LED device for a period of time, the heating current is stopped, and a testing current, i.e., a pulse current with a short pulse width, is used to continuously measure a plurality of forward voltages of the LED device. In this condition, the forward voltage of the LED device increases rapidly so that a voltage difference dv (a positive value) increases continuously over time. In particular, the LED device with unqualified package interface will exhibit a larger positive voltage difference than the LED device with a qualified package interface.

In a seventh embodiment of the present invention as shown in FIG. 12, the testing control unit 24 provides a first control signal S1 to command the current source 22 to generate a heating current for the LED device 25. After the heating current has been provided for a time interval th, the testing control unit 24 provides a signal S2 to command the voltage measuring unit 23 to measure a forward voltage V1 of the LED device 25, and provides a second control signal S1′ to command the current source 22 to stop providing the heating current. Subsequently, the testing control unit 24 provides a third control signal S1″ to command the current source 22 to generate a testing current with a short pulse width for the LED device 25 after a time interval, and provides another signal to S3 command the voltage measuring unit 23 to measure a forward voltage V2 of the LED device 25. As shown in FIG. 12, the values of the heating current and the testing current are equal to the rated current value of the LED device. The pulse width of the testing current is between 20 μsec and 100 μsec.

The testing control unit 24 reads and records the forward voltages V1 and V2 of the LED device 25 measured by the voltage measuring unit 23, and calculates the voltage difference between them. Subsequently, the testing control unit 24 determines that the LED device 25 is defective if the voltage difference is larger than a predetermined threshold value. Because the LED device 25 is heated by the heating current for the interval th and is measured by the testing current with the short pulse width, the junction temperature of the LED device 25 will decrease after the heating interval th, and the measured voltage difference will be a positive value.

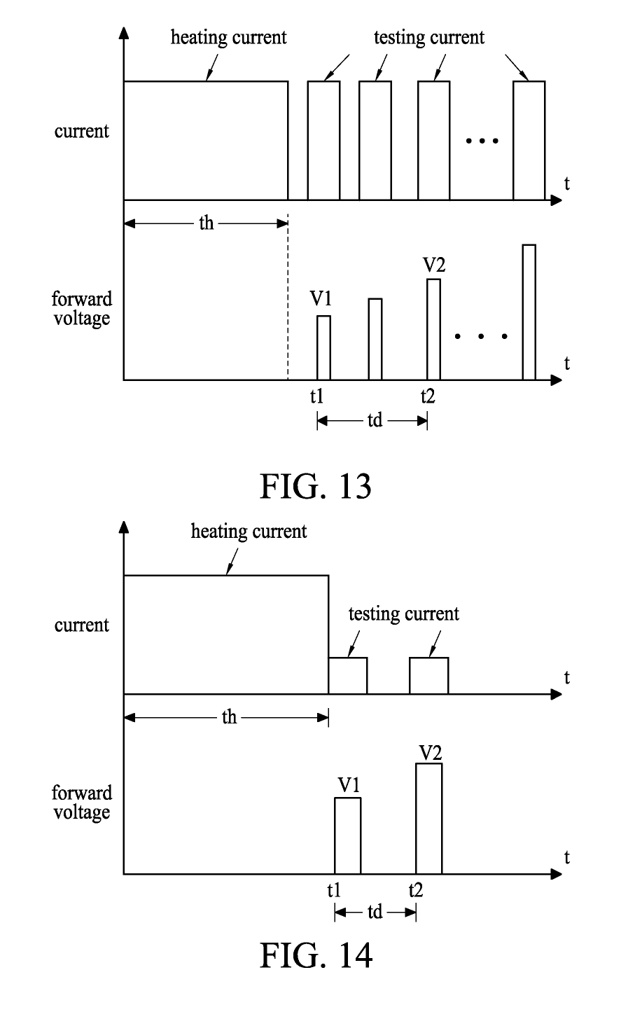

Similarly, for obtaining a plurality of forward voltages at different times in accordance with a eighth embodiment as shown in FIG. 13, after the heating current has been stopped, the testing control unit 24 provides a plurality of control signals to command the current source 22 to generate a short pulse current in sequence for the LED device 25, and provides a plurality of signals to command the voltage measuring unit 23 to continuously measure forward voltages of the LED device 25. The current source 22 provides the heating current to the LED device 25 during a heating interval th. The junction temperature of the LED device 25 decreases after the heating interval th. As shown in FIG. 13, the testing current is a pulse current with a pulse width about 20 μsec to 100 μsec, and the values of the heating current and the testing current are equal to the rated current value of the LED device.

The testing control unit 24 reads and records the plurality of forward voltages of the LED device 25 measured by the voltage measuring unit 23, and calculates the voltage difference between two forward voltages V1 and V2 of the LED device 25 measured at two predetermined times t1 and t2, wherein the plurality of forward voltages increase continuously over time, and the value of the forward voltage V1 is smaller than that of the forward voltage V2. Subsequently, the testing control unit 24 determines that the LED device 25 is defective if the voltage difference between the forward voltages V1 and V2 is larger than a predetermined threshold value.

In a ninth embodiment of the present invention as shown in FIG. 14, the testing control unit 24 provides a first control signal S1 to command the current source 22 to generate a heating current for the LED device 25. Subsequently, the testing control unit 24 provides a second control signal S1′ to command the current source 22 to stop providing the heating current after a heating time interval th, and provides a third control signal S1″ to command the current source 22 to provide a pulse testing current for the LED device 25. Subsequently, the testing control unit 24 provides a signal S2 to command the voltage measuring unit 23 to measure a forward voltage V1 of the LED device 25. The testing control unit 24 provides a fourth control signal S1′″ to command the current source 22 to provide the pulse testing current after a time interval td, and provides another signal S3 to command the voltage measuring unit 23 to measure a forward voltage V2 of the LED device 25.

The testing control unit 24 reads and records the forward voltages V1 and V2 of the LED device 25 measured by the voltage measuring unit 23, and calculates the voltage difference between them. Subsequently, the testing control unit 24 determines that the LED device 25 is defective if the voltage difference is larger than a predetermined threshold value. Because the LED device 25 is heated by the heating current for the interval th and is measured by the testing current with a short pulse width, the junction temperature of the LED device 25 will decrease after the heating interval th, and the measured voltage difference will be a positive value. In this embodiment, the value of the heating current is equal to the rated current value of the LED device 25, and the value of the testing current is between 0.1 mA and 5 mA for reducing the heating effect of a large current. The pulse width of the testing current is between 20 μsec and 100 μsec. However, the present invention should not be limited to the embodiment.

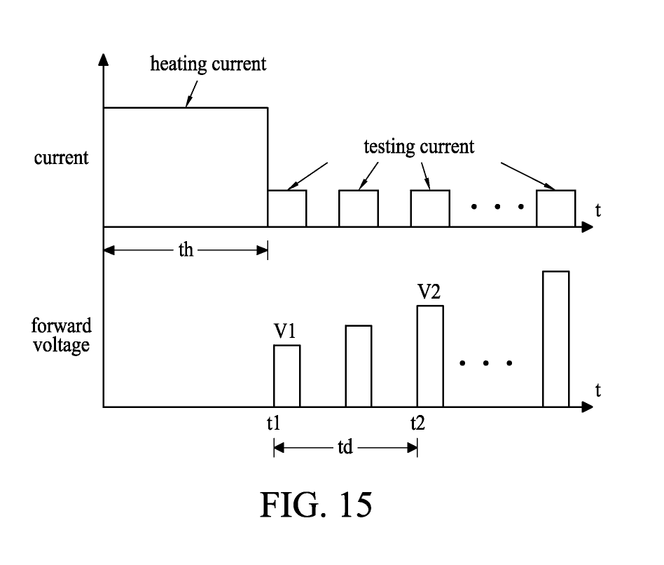

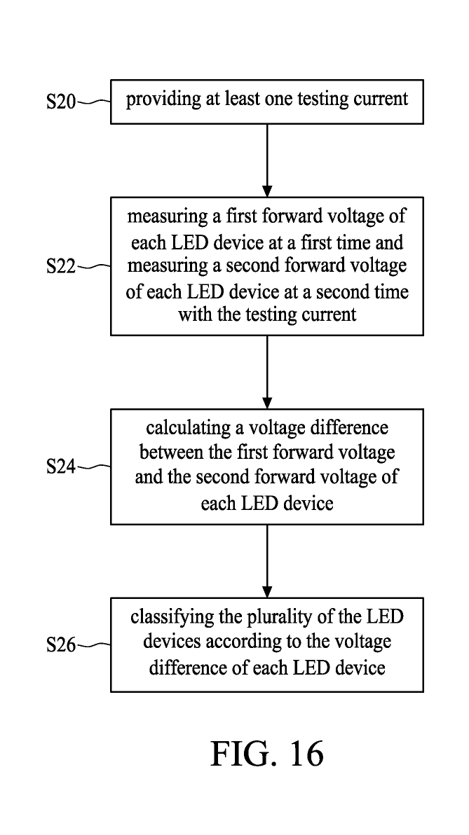

Similarly, for obtaining a plurality of forward voltages at different times in accordance with a tenth embodiment as shown in FIG. 15, after the heating current has been stopped, the testing control unit 24 provides a plurality of control signals to command the current source 22 to generate a short pulse current in sequence for the LED device 25, and provides a plurality of signals to command the voltage measuring unit 23 to continuously measure forward voltages of the LED device 25. The current source 22 provides the heating current to the LED device 25 during a heating interval th. The junction temperature of the LED device 25 decreases after the heating interval th.

The testing control unit 24 reads and records the plurality of forward voltages of the LED device 25 measured by the voltage measuring unit 23 after the time interval th, and calculates the voltage difference between two forward voltages V1 and V2 of the LED device 25 measured at two predetermined times t1 and t2, wherein the plurality of forward voltages increase continuously over time, and the value of the forward voltage V1 is smaller than that of the forward voltage V2. Subsequently, the testing control unit 24 determines that the LED device 25 is defective if the voltage difference between the forward voltages V1 and V2 is larger than a predetermined threshold value.

In the aforementioned embodiments, when the testing control unit 24 provides a control signal to command the current source 22 to generate a testing current for the LED device 25, and provides a signal to command the voltage measuring unit 23 to measure a forward voltage of the LED device 25, a time delay can be set before voltage measuring to reduce voltage error. The time delay is between 5 μsec and 50 μsec. The time interval td of the voltage measurement and the heating interval th can be set according to the amount of the testing current and the types and the structures of the LED device 25, and the general time interval td and interval th are between 100 μsec and 1 sec. However, the present invention should not be limited to the embodiment. The voltage measuring unit 23 of the inspection apparatus 20 is a rapid voltage measuring apparatus with high resolution, and the degree of resolution should be less than 5 mV while the preferable degree of resolution is less than 1 mV. However, the present invention should not be limited to the embodiment. The sampling rate should be greater than 200,000 times per second, and the preferable sampling rate is one million times per second. However, the present invention should not be limited to the embodiment.

The present invention further provides a computer program product having computer readable program instructions for carrying out any of the aforementioned LED package interface inspection methods. The computer program product includes a computer readable storage medium having computer readable program instructions embodied therein, the computer readable program instructions comprising: program instructions configured to provide at least one current to the LED device, program instructions configured to measure a first forward voltage of the LED device at a first time and to measure a second forward voltage of the LED device at a second time with the at least one current, program instructions configured to calculate a voltage difference between the first forward voltage and the second forward voltage, and program instructions configured to determine whether the LED device is defective based on whether the voltage difference is larger than a predetermined threshold value.

When the package interfaces of a plurality of LED device are inspected, the testing control unit 24 can classify the plurality of the LED devices 25 according to a voltage difference of each LED device. FIG. 17 shows the flow chart of another embodiment of the LED package interface inspection method of the present invention, which includes providing at least one testing current in step S20, measuring a first forward voltage of each LED device at a first time and measuring a second forward voltage of each LED device at a second time with the testing current in step S22, calculating a voltage difference between the first forward voltage and the second forward voltage of each LED device in step S24, and classifying the plurality of the LED devices according to the voltage difference of each LED device in step S26. The first time of measuring each LED device is the same, and the second time of measuring each LED device is the same. A testing control unit can be adopted to determine that the LED device is defective if the voltage difference is larger than a threshold value predetermined by an inspection apparatus.

The present invention provides a rapid inspection apparatus and a method for a light emitting diode (LED) package interface. Based on the phenomenon whereby an increase in the LED junction temperature results in a decrease in LED forward voltage and a decrease in the LED junction temperature results in an increase in LED forward voltage, the voltage difference of an LED device can be measured according to differences in time interval of a testing current and a heating current, and according to differences in current value of the testing current and the heating current. Therefore, differences in measurable qualities of the package interface, such as die bonding quality, between LED devices can be determined within seconds. The inspection apparatus and method can be combined with the general apparatuses of rapid optical and electrical properties inspection for sorting unqualified die bonding devices before the LED

The above-described exemplary embodiments are intended to be illustrative of the invention principle only. Those skilled in the art may devise numerous alternative embodiments without departing from the scope of the following claims.

We claim:

1. A light emitting diode (LED) package interface inspection apparatus for an LED device, comprising:
a current source;
a voltage measuring unit; and
a testing control unit providing at least one control signal to command the current source to output at least one current to the LED device, and providing at least two signals to command the voltage measuring unit to measure a first forward voltage of the LED device at a first time and a second forward voltage of the LED device at a second time;
wherein the testing control unit calculates a voltage difference between the first forward voltage and the second forward voltage, and determines that the LED device is defective if the voltage difference is larger than a predetermined threshold value.

2. The LED package interface inspection apparatus of claim 1, wherein the at least one current is a testing current, the current source continues to provide the testing current to the LED device, and the voltage measuring unit continues to measure a plurality of forward voltages of the LED device, of which the first forward voltage of the LED device is measured at the first time and the second forward voltage of the LED device is measured at the second time.

3. The LED package interface inspection apparatus of claim 2, wherein a value of the testing current is equal to a rated current value of the LED device.

4. The LED package interface inspection apparatus of claim 1, wherein an interval between the first time and the second time is between 100 μsec and 1 sec.

5. The LED package interface inspection apparatus of claim 1, wherein the at least one current is a testing current and a heating current, a value of the testing current is between 0.1 mA and 5 mA, and a value of the heating current is equal to a rated current value of the LED device, wherein the current source respectively provides the testing current to the LED device at the first time and the second time, the current source provides the heating current to the LED device during a heating interval before the second time, and the heating interval is between 100 μsec and 1 sec.

6. The LED package interface inspection apparatus of claim 1, wherein the current source alternately provides the testing current and the heating current to the LED device, and the voltage measuring unit continues to measure a plurality of forward voltages of the LED device, of which the first forward voltage of the LED device is measured at the first time when the testing current is provided, and the second forward voltage of the LED device is measured at the second time when the testing current is provided.

7. The LED package interface inspection apparatus of claim 1, wherein the at least one current comprises a first and a second testing current, and the current source respectively provides the first and second testing currents to the LED device at the first time and the second time, wherein the first and the second testing currents are pulse current, the pulse width of the second testing current is greater than that of the first testing current, and the values of the first and second testing currents are equal to a rated current value of the LED device.

8. The LED package interface inspection apparatus of claim 7, wherein the second testing current is provided in sequence with gradually increased pulse widths, and the voltage measuring unit continues to measure a plurality of forward voltages of the LED device, of which the first forward voltage of the LED device is measured at the first time and the second forward voltage of the LED device is measured at the second time.

9. The LED package interface inspection apparatus of claim 1, wherein the at least one current comprises a heating current and a testing current, the current source provides the heating current to the LED device during a heating interval until the first time, and provides the testing current to the LED device at the second time, wherein the heating current and the testing current are pulse currents, the pulse width of the heating current is greater than that of the testing current, and the values of both currents are equal to a rated current value of the LED device, wherein an interval between the first time and the second time is between 100 μsec and 1 sec.

10. The LED package interface inspection apparatus of claim 9, wherein the current source continues to provide the testing current to the LED device, and the voltage measuring unit continues to measure a plurality of forward voltages of the LED device, of which the first forward voltage of the LED device is measured at the first time and the second forward voltage of the LED device is measured at the second time.

11. The LED package interface inspection apparatus of claim 1, wherein the at least one current comprises a heating current and a testing current, a value of the testing current is less than that of the heating current, the current source provides the heating current to the LED device during a heating interval before the first time, and provides the testing current to the LED device at the first and second times respectively, wherein a value of the heating current is equal to a rated current value of the LED device, the value of the testing current is between 0.1 mA and 5 mA, and the interval between the first time and the second time is between 100 μsec and 1 sec.

12. The LED package interface inspection apparatus of claim 11, wherein the current source continues to provide the testing current to the LED device, and the voltage measuring unit continues to measure a plurality of forward voltages of the LED device with the testing current, of which the first forward voltage of the LED device is measured at the first time and the second forward voltage of the LED device is measured at the second time.

13. The LED package interface inspection apparatus of claim 1, wherein the LED device comprises an LED die and a package carrier, and the package interface comprises a die-bonding interface formed between the LED die and the package carrier.

14. The LED package interface inspection apparatus of claim 13, wherein the LED device further comprises a circuit board, and the package interface further comprises an assembly interface formed between the package carrier and the circuit board.

15. The LED package interface inspection apparatus of claim 1, wherein a degree of resolution of the voltage measuring unit is less than 1 mV, and a sampling rate is higher than 200,000 times per second.

16. A light emitting diode (LED) package interface inspection method for an LED device, comprising the steps of:
providing at least one current to the LED device;
measuring a first forward voltage of the LED device at a first time and measuring a second forward voltage of the LED device at a second time with the at least one current;
calculating a voltage difference between the first forward voltage and the second forward voltage; and
determining whether the LED device is defective based on whether the voltage difference is larger than a predetermined threshold value.

17. The LED package interface inspection method of claim 16, wherein the current is a long pulse current, and a plurality of forward voltages of the LED device, including the first forward voltage and the second forward voltage, are measured with the current.

18. The LED package interface inspection method of claim 17, wherein a value of the current is equal to a rated current value of the LED device.

19. The LED package interface inspection method of claim 16, wherein an interval between the first time and the second time is between 100 μsec and 1 sec.

20. The LED package interface inspection method of claim 16, wherein the at least one current comprises a testing current and a heating current, a value of the testing current is between 0.1 mA and 5 mA, and a value of the heating current is equal to a rated current value of the LED device, wherein the testing current is provided to the LED device at the first time and the second time, the heating current is provided to the LED device during a heating interval before the second time, and the heating interval is between 100 μsec and 1 sec.

21. The LED package interface inspection method of claim 20, wherein the testing current and the heating current are alternatively provided to the LED device, and a plurality of forward voltages of the LED device, including the first forward voltage and the second forward voltage, are measured with the testing current.

22. The LED package interface inspection method of claim 16, wherein the at least one current comprises a first and a second testing current, the first testing current is a pulse current and is provided at the first time, and the second testing current is the pulse current and is provided at the second time, wherein a pulse width of the second testing current is greater than that of the first testing current, and the values of the first and second testing currents are equal to a rated current value of the LED device.

23. The LED package interface inspection method of claim 22, wherein the second testing current is provided in sequence with gradually increased the pulse widths, and a plurality of forward voltages of the LED device, including the first forward voltage and the second forward voltage, are measured with the at least one current.

24. The LED package interface inspection method of claim 16, wherein the at least one current comprises a heating current and a testing current, the current source provides the heating current to the LED device during a heating interval until the first time, and provides the testing current to the LED device at the second time, wherein the heating current and the testing current are pulse currents, a pulse width of the heating current is greater than that of the testing current, and the values of both currents are equal to a rated current value of the LED device, wherein an interval between the first time and the second time is between 100 μsec and 1 sec.

25. The LED package interface inspection method of claim 24, wherein the testing current is provided in sequence, and a plurality of forward voltages of the LED device, including the first forward voltage and the second forward voltage, are measured with the at least one current.

26. The LED package interface inspection method of claim 16, wherein the at least one current comprises a heating current and a testing current, a value of the testing current is less than that of the heating current, the heating current is provided to the LED device during a heating interval before the first time, and the testing current is provided to the LED device at the first and second times respectively, wherein a value of the heating current is equal to a rated current value of the LED device, the value of the testing current is between 0.1 mA and 5 mA, and an interval between the first time and the second time is between 100 μsec and 1 sec.

27. The LED package interface inspection method of claim 26, wherein the testing current is provided in sequence, and a plurality of forward voltages of the LED device, including the first forward voltage and the second forward voltage, are measured with the testing current.

28. The LED package interface inspection method of claim 16, wherein the LED device comprises an LED die and a package carrier, and the package interface comprises a die-bonding interface formed between the die and the package carrier.

29. The LED package interface inspection method of claim 28, wherein the LED device further comprises a circuit board, and the package interface further comprises an assembly interface formed between the package carrier and the circuit board.

30. A light emitting diode (LED) package interface inspection method for a plurality of LED devices, comprising the steps of:
providing at least one testing current;
measuring a first forward voltage of each LED device at a first time and measuring a second forward voltage of each LED device at a second time with the testing current;
calculating a voltage difference between the first forward voltage and the second forward voltage of each LED device; and
classifying the plurality of LED devices according to the voltage difference of each LED device.

31. The LED package interface inspection method of claim 31, wherein the first time of measuring each LED device is the same, and the second time of measuring each LED device is the same.

32. A computer program product for inspecting a package interface of a light emitting diode (LED) device, the computer program product comprising a computer readable storage medium having computer-readable program instructions embodied in the medium, the computer-readable program instructions comprising:
first instructions for providing at least one current to the LED device;
second instructions for measuring a first forward voltage of the LED device at a first time and measuring a second forward voltage of the LED device at a second time with the at least one current;
third instructions for calculating a voltage difference between the first forward voltage and the second forward voltage; and
fourth instructions for determining whether the LED device is defective based on whether the voltage difference is larger than a predetermined threshold value.

33. The computer program product of claim 32, wherein the current is a long pulse current, and a plurality of forward voltages of the LED device, including the first forward voltage and the second forward voltage, are measured with the current.

34. The computer program product of claim 33, wherein a value of the current is equal to a rated current value of the LED device.

35. The computer program product of claim 32, wherein an interval between the first time and the second time is between 100 μsec and 1 sec.
